(19) United States
(12) Patent Application Publication
(10) Pub. No.: US 2022/0328339 A1
(43) Pub. Date: Oct. 13, 2022

(54) HETEROGENEOUS STRUCTURES AND PROCESSING METHODS

(71) Applicant: X-Celeprint Limited, Dublin (IE)

(72) Inventors: Ronald S. Cok, Rochester, NY (US); Ruggero Loi, Ovens (IE)

(21) Appl. No.: 17/713,814

(22) Filed: Apr. 5, 2022

Related U.S. Application Data
(60) Provisional application No. 63/173,347, filed on Apr. 9, 2021.

(51) Int. Cl. H01L 21/683; B41M 3/00

(52) U.S. Cl. CPC H01L 21/6835; B41M 3/00; H01L 2221/68322; H01L 2221/68354; H01L 2221/68368

(57) ABSTRACT

An example of a method of making a heterogeneous semiconductor structure, includes providing a first substrate including a first material; providing a second substrate including a printable processable coupon, wherein the coupon includes a second material different from the first material; and printing the coupon to the first substrate. The method can includes processing the coupon on the first substrate to form an integrated circuit. An example of a heterogeneous structure includes a substrate including a first material and one or more non-native coupons disposed on the substrate, the coupon including a second material different from the first material. The second material can be or comprise an epitaxial material, such as a compound semiconductor material. The first material can be or comprise an elemental semiconductor, such as silicon.

### PRIORITY APPLICATION

The present application claims the benefit of U.S. Provisional Patent Application No. 63/173,347, filed on Apr. 9, 2021, the disclosure of which is hereby incorporated by reference herein in its entirety.

### TECHNICAL FIELD

This disclosure relates generally to heterogeneous wafer structures for processing and methods of processing heterogeneous wafers in a common process.

### BACKGROUND

Modern silicon wafers are processed at a very high resolution, for example having feature sizes that are 10 nm or less in extent or having features that are separated by 10 nm or less, or both, to make dense and fast integrated circuits. Such small features sizes are a result of expensive photolithographic machinery whose cost is justified in terms of the very large volumes of silicon integrated circuits, for example CMOS circuits, that can be processed. The large volume of silicon integrated circuits has, in turn, led to the development of low-cost and relatively large source silicon substrates, for example 300 mm in diameter. The combination of low-cost and large silicon source materials and sophisticated process equipment (particularly high-resolution mask and exposure equipment) enables the low cost and ubiquitous silicon integrated circuits that are present in the vast majority of electronic devices today.

However, silicon is not the optimal material for all desirable semiconductor devices. For example, compound semiconductor materials, such as GaAs and GaN and many other III/V material combinations, can provide, for example, greater electron mobility, superior light emission, or superior sensor sensitivity and are therefore more suitable for certain applications, such as high-power electrical devices and photonic (e.g., lasers and light-emitting diodes) devices among others. Because these applications are often relatively recently developed and are manufactured at a relatively lower volume than silicon devices, the availability and cost of photolithographic processing equipment and wafer sizes for compound semiconductor materials is disadvantaged with respect to silicon. Essentially, compound semiconductor materials and processing are more expensive and manufactured at lower resolutions (making larger components) than silicon.

### SUMMARY

It would be useful to manufacture compound semiconductor devices at resolutions and at costs similar to silicon devices but associated equipment and plant costs, availability, and reliability, are currently prohibitive to such an end.

This objective can be achieved by methods and structures of the present disclosure. In summary, unprocessed crystalline epitaxial material (epi coupons) can be released from a source wafer (e.g., from an SOI wafer) and printed (e.g., micro-transfer printed) to a silicon (or other) substrate and processed at resolutions available to silicon photolithography equipment to make integrated circuits in the epi coupons. Each epi coupon can be relatively small (for example less than 200, 100, 50, 20, or 10 microns in length or width or both. Because micro-transfer printing can transfer large numbers (e.g., 10,000-50,000, or even more) of coupons at a time several times a minute, making a (e.g., standard size) silicon wafer with epi coupons from one or more source compound semiconductor source wafers is relatively simple and inexpensive and provides excellent utilization of expensive compound semiconductor source wafers (e.g., minimizes waste), thereby reducing material costs and minimizing additional processing costs.

Chemistries and process rates for processing compound semiconductors can differ in some, but not all, materials and photolithographic processes. According to the present disclosure, areas on the substrate covered with the epi coupons can be selectively and pattern-wise coated with a process-protective material to expose either the coupons or the silicon and protect the other. Such materials can be materials such as dielectrics, oxides, nitrides, metals, or amorphous silicon depending on the process desired and the target material for processing. The exposed material is then processed at the substrate resolution and the process-protective material can then be removed. In some cases, where processing methods and material are compatible, both materials can be processed at once. The silicon substrate can also be processed (before or after epi coupons are disposed on the silicon substrate) to form a circuit and conventional metallization processes can be used to form electrical connections between the circuits in the silicon and the epi coupons. In some cases, the high-resolution processed epi coupons can be transferred (e.g., by dicing or by micro-transfer printing) to another destination substrate without connecting to circuits on the silicon substrate.

In some embodiments, a method of making a heterogeneous (e.g., semiconductor) (e.g., wafer) structure includes providing a first substrate (e.g., wafer) (e.g., a process-ready wafer, e.g., a 25 mm, 51 mm, 76 mm, 100 mm, 125 mm, 150 mm, 200 mm, 300 mm, 450 mm, or 675 mm wafer) including a first material. A second substrate (e.g., wafer) including a printable (e.g., micro-transfer printable) processable coupon can be provided. The coupon can include a second material different from the first material. In some embodiments, the method includes printing (e.g., micro-transfer printing) the coupon to the first substrate (e.g., with a transfer device, e.g., a stamp). In some embodiments, the coupon on the first substrate is then processed to form an integrated circuit.

In some embodiments, the first substrate is a semiconductor substrate including a substrate circuit and the method includes electrically connecting the substrate circuit to an integrated circuit formed in or on the coupon. In some embodiments, the coupon includes (e.g., consists essentially of) epitaxial material (e.g., is an epitaxial layer). In some embodiments, the epitaxial material is unprocessed (e.g., wherein the epitaxial layer is an unprocessed epitaxial layer) during the printing.

In some embodiments, the method includes pattern-wise covering (e.g., coating) the first substrate with a protection layer (e.g., a process-protective coating) and subsequently processing the coupon separately from the first substrate. In some embodiments, the method includes pattern-wise covering (e.g., coating) the coupon with a protection layer (e.g., a process-protective coating) and subsequently processing the first substrate separately from the coupon.

In some embodiments, the first substrate is process-capable at a first resolution and the second substrate is process capable at a second resolution different from the first resolution and the method includes processing the coupon at the first resolution (e.g., to form the integrated circuit). In some embodiments, the first resolution is higher than the second resolution.

In some embodiments, the first substrate is an elemental semiconductor substrate (e.g., a silicon, germanium, or tin substrate). In some embodiments, the second substrate is a compound semiconductor substrate.

In some embodiments, the coupon is a first coupon and the integrated circuit is a first integrated circuit, and the method includes providing a third substrate including a printable processable second coupon. The second coupon can include a third material different from the first material and different from the second material. In some embodiments, the method includes printing (e.g., micro-transfer printing) the second coupon to the first substrate (e.g., with a transfer device, e.g., a stamp). In some embodiments, the method includes processing the second coupon to form a second integrated circuit [e.g., wherein the second coupon includes a broken (e.g., fractured) or separated tether after the printing]. In some embodiments, the third substrate is a compound semiconductor substrate.

In some embodiments, the second coupon includes (e.g., consists essentially of) epitaxial material (e.g., is an epitaxial layer). In some embodiments, the epitaxial material is unprocessed (e.g., wherein the epitaxial layer is an unprocessed epitaxial layer) during the printing.

In some embodiments, the first substrate is process-capable at a first resolution and the third substrate is process capable at a third resolution different from the first resolution and wherein the second coupon is processed at the first resolution. In some embodiments, the second substrate is process capable at a second resolution different from the first resolution and different from the third resolution. In some embodiments, the first resolution is higher than the third resolution.

In some embodiments, the method includes pattern-wise coating the first substrate with a process-protective coating and processing the first coupon and the second coupon separately from the first substrate. In some embodiments, the method includes pattern-wise coating the first substrate and the first coupon with a process-protective coating and processing the second coupon separately from the first substrate and the first coupon.

In some embodiments, the first substrate is a semiconductor substrate including a substrate circuit and the method includes electrically connecting the substrate circuit to the second integrated circuit.

In some embodiments, the method includes patterning the first substrate and the second coupon in a common step. In some embodiments, the method includes patterning the first substrate and the coupon in a common step.

In some embodiments, the first substrate is crystalline, the second substrate is crystalline, or both.

In some embodiments, the coupon includes a broken (e.g., fractured) or separated tether after the coupon is printed to the first substrate.

In some embodiments, a heterogeneous (e.g., semiconductor) (e.g., wafer) structure includes a first substrate including a first material process capable at a first resolution. In some embodiments, the heterogeneous structure includes a non-native coupon disposed on the first substrate, the coupon including a second material different from the first material (e.g., and including a broken (e.g., fractured) or separated tether], the second material process capable at a second resolution less than the first resolution. In some embodiments, the heterogeneous structure includes an integrated circuit formed in or on the coupon at the first resolution.

In some embodiments, the coupon is a first coupon, the integrated circuit is a first integrated circuit, and the heterogeneous structure includes a second non-native coupon disposed on the first substrate, the second coupon including a third material different from the first material [e.g., and including a broken (e.g., fractured) or separated tether], the third material process capable at a third resolution less than the first resolution; and a second integrated circuit formed in or on the coupon at the first resolution.

In some embodiments, a heterogeneous (e.g., semiconductor) (e.g., wafer) structure includes a substrate (e.g., process-ready wafer, e.g., a 25 mm, 51 mm, 76 mm, 100 mm, 125 mm, 150 mm, 200 mm, 300 mm, 450 mm, or 675 mm wafer) including a first material (e.g., that is process capable at a first resolution). In some embodiments, the heterogeneous structure includes one or more non-native coupons (e.g., a plurality of non-native coupons) disposed on the substrate, the one or more coupons including a second material different from the first material (e.g., wherein the second material is process capable at a second resolution less than the first resolution). In some embodiments, the heterogeneous structure includes an integrated circuit formed in or on each of the one or more non-native coupons.

In some embodiments, the first material is a first semiconductor material and the second material is a second semiconductor material. In some embodiments, the second material is a compound semiconductor material (e.g., a III-V semiconductor material or a II-VI semiconductor material). In some embodiments, the first material is an intrinsic semiconductor. In some embodiments, one or both of the first material and the second material is a doped semiconductor. In some embodiments, the first material is an elemental semiconductor (e.g., silicon, e.g., having a {100} or {111} orientation, or germanium or tin). In some embodiments, the one or more non-native coupons are coupon(s) of epitaxial material (e.g., a layer of epitaxial material). In some embodiments, the epitaxial material is unprocessed (e.g. the layer of epitaxial material is an unprocessed epitaxial layer).

In some embodiments, the one or more non-native coupons each include a broken (e.g., fractured) or separated tether.

In some embodiments, the second material of each of the one or more non-native coupons is an epitaxial material (e.g., is a layer of epitaxial material).

In some embodiments, an integrated circuit formed in or on each of the one or more non-native coupons.

In some embodiments, the substrate is process capable at a first resolution and the integrated circuit is formed at the first resolution.

In some embodiments, the heterogeneous structure includes a protection layer (e.g., dielectric layer) [e.g., oxide, nitride, metal, or amorphous material (e.g., amorphous silicon)] (e.g., a patterned protection layer) that covers the substrate while leaving at least a portion of each of the one or more coupons exposed for processing. In some embodiments, the heterogeneous structure includes a protection layer (e.g., dielectric layer) [e.g., oxide, nitride, metal, or amorphous material (e.g., amorphous silicon)] (e.g., a patterned protection layer) that covers the one or more coupons while leaving at least a portion of the substrate exposed for processing.

In some embodiments, the first material is anisotropically etchable. In some embodiments, the heterogeneous structure includes one or more anchors disposed on the substrate, wherein each of the one or more coupons is attached to one or more of the one or more anchors by one or more tethers. In some embodiments, each of the one or more coupons is suspended over the substrate by the one or more tethers such that a gap is defined between each of the one or more coupons and the substrate.

In some embodiments, the substrate is a semiconductor substrate including a substrate circuit electrically connected to an integrated circuit formed on or in each of the one or more coupons.

In some embodiments, the heterogeneous structure includes one or more non-native second coupons (e.g., a plurality of non-native second coupons) disposed on the substrate, the one or more second coupons including a third material different from the first material and different from the second material [e.g., wherein the third material is an elemental semiconductor material or a compound semiconductor material (e.g., a III-V semiconductor material or a II-VI semiconductor material), e.g., that is an intrinsic semiconductor or a doped semiconductor] (e.g., wherein the second material is process capable at a second resolution less than the first resolution).

### BRIEF DESCRIPTION OF THE DRAWINGS

Drawings are presented herein for illustration purposes, not for limitation. Drawings are not necessarily drawn to scale. The foregoing and other objects, aspects, features, and advantages of the disclosure will become more apparent and may be better understood by referring to the following description taken in conjunction with the accompanying drawings, in which:

FIGS. 1-8 illustrate methods of forming a heterogeneous structure that includes integrated circuits formed in or on coupons that are electrically connected to a substrate circuit, according to illustrative embodiments of the present disclosure; and

FIG. 9-11 illustrate methods of forming a source wafer starting from a heterogeneous structure according to FIG. 5, according to illustrative embodiments of the present disclosure.

### DETAILED DESCRIPTION OF CERTAIN EMBODIMENTS

It is contemplated that systems, devices, methods, and processes of the disclosure encompass variations and adaptations developed using information from the embodiments described herein. Adaptation and/or modification of the systems, devices, methods, and processes described herein may be performed by those of ordinary skill in the relevant art.

Throughout the description, where articles, devices, and systems are described as having, including, or comprising specific components, or where processes and methods are described as having, including, or comprising specific steps, it is contemplated that, additionally, there are articles, devices, and systems according to certain embodiments of the present disclosure that consist essentially of, or consist of, the recited components, and that there are processes and methods according to certain embodiments of the present disclosure that consist essentially of, or consist of, the recited processing steps.

It should be understood that the order of steps or order for performing certain action is immaterial so long as operability is not lost. Moreover, two or more steps or actions may be conducted simultaneously.

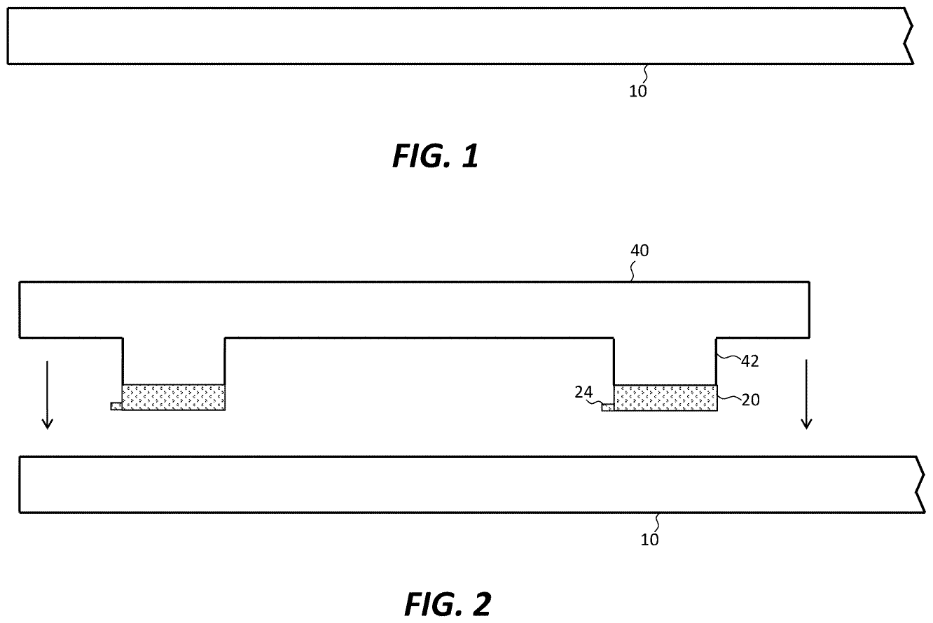

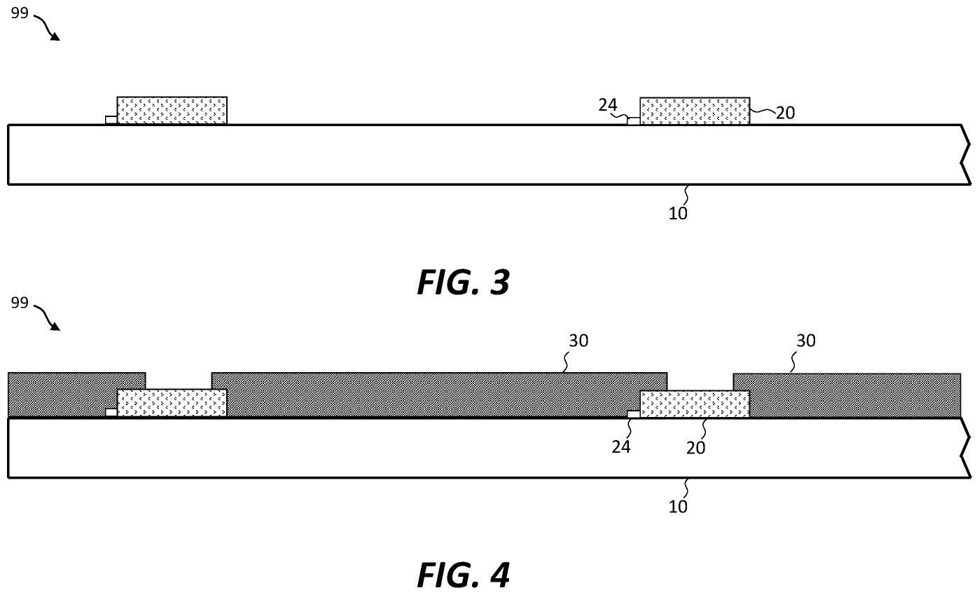

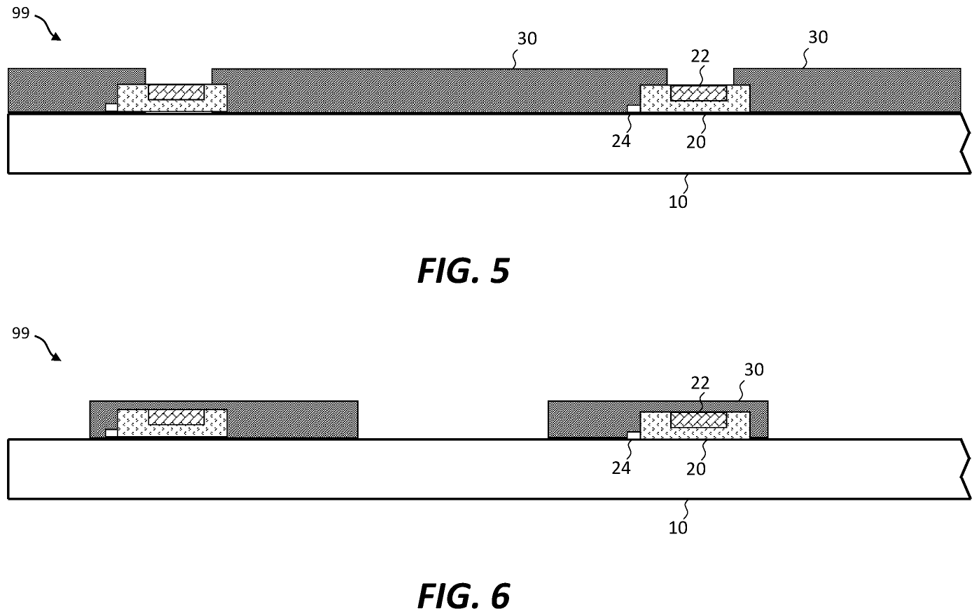

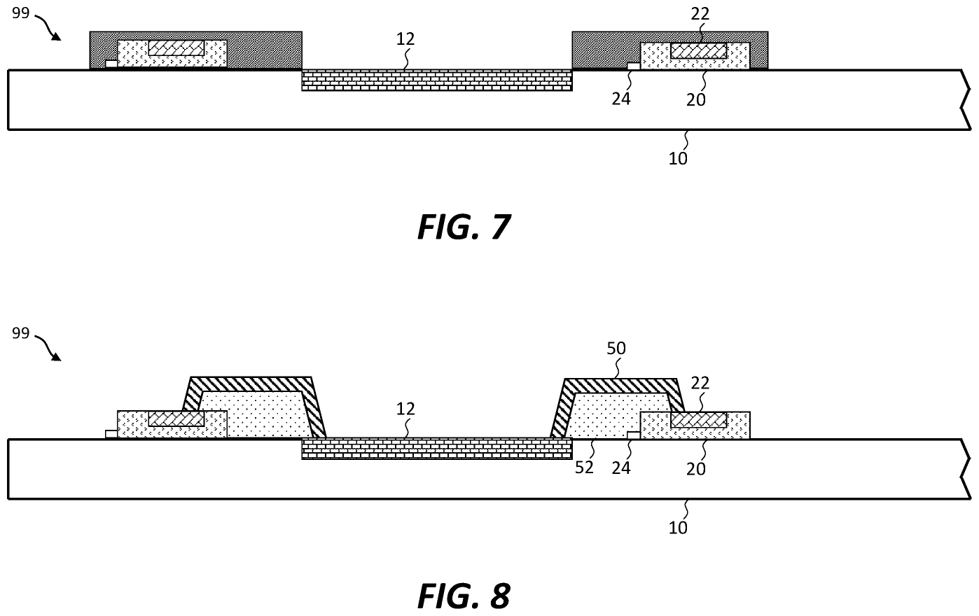

FIG. 1 illustrates a step of providing a substrate 10 (e.g., a wafer) (e.g., a silicon wafer). FIG. 2 illustrates a step of micro-transfer printing coupons 20 onto substrate 10 with an elastomer stamp 40 including posts 42. FIG. 3 illustrates coupons 20 disposed on substrate 10, where coupons 20 include a material different from a material included in substrate 10. For example, coupons 20 include a compound semiconductor material (e.g., processable at a second resolution) and substrate 10 includes an elemental semiconductor (e.g., silicon) (e.g., processable at a first resolution higher than the second resolution). FIG. 4 illustrates covering (e.g., coating) substrate 10 with protection layer 30 leaving portions of coupons 20 exposed for processing. FIG. 5 illustrates forming integrated circuits 22 in or on coupons 20. FIG. 6 illustrates protection layer 30 having been removed to expose substrate 10 again and covering (e.g., coating) coupons 20 with a new protection layer 30 leaving portions of substrate 10 exposed for processing. FIG. 7 illustrates forming substrate circuit 12 (e.g., an integrated circuit) in or on substrate 10. FIG. 8 illustrates protection layer 30 having been removed from coupons 20 and electrically connecting substrate circuit 12 in or on substrate 10 to integrated circuits 22 in or on coupons 20 using electrical connections 50. Dielectric layer 52 is used to prevent unwanted electrical contact between portions of coupon 20 and electrical connections 50.

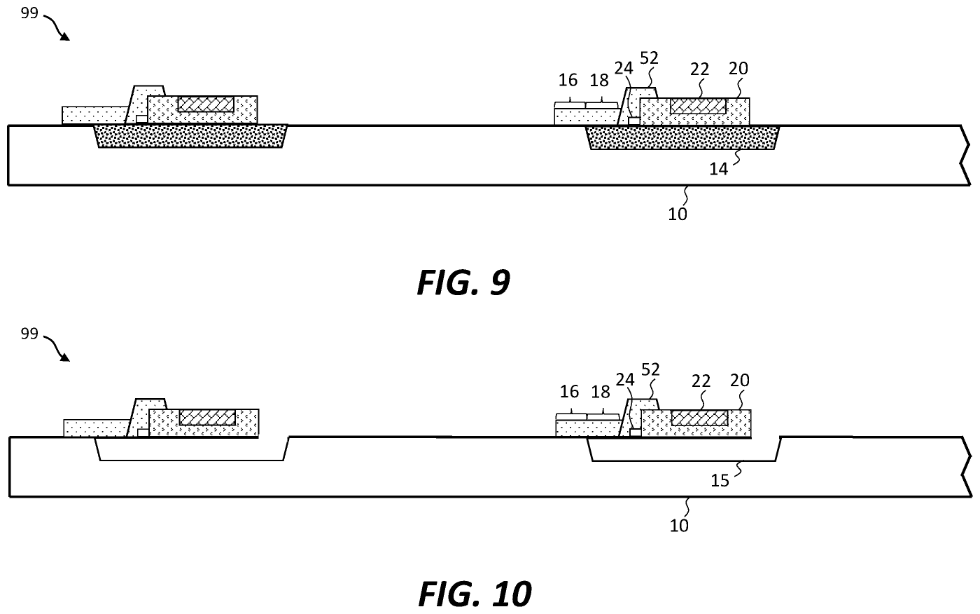

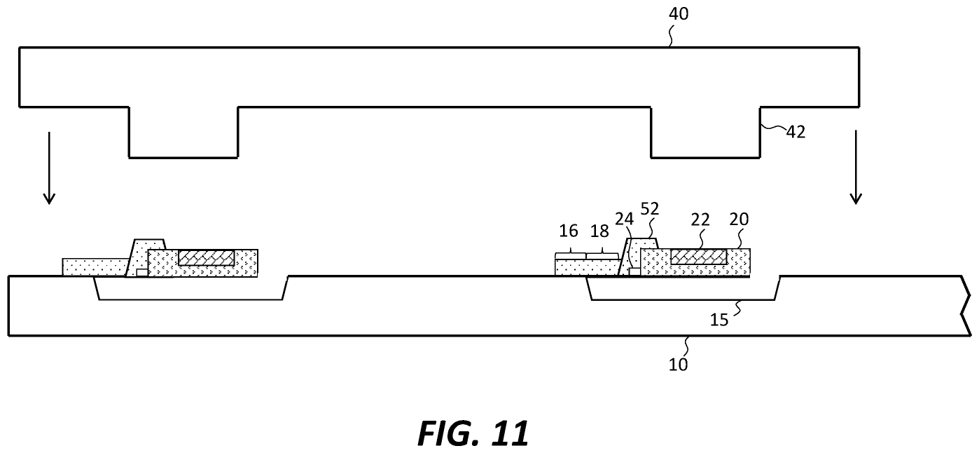

FIG. 9 illustrates a heterogeneous structure that includes printable processed coupons 20. In this way, coupons 20 can be printed to substrate 10 and processed using a process (e.g., at a resolution) amenable to processing for substrate 10 (e.g., a silicon process for a 300 nm silicon wafer) before being printed to a destination substrate (e.g., thereby enabling higher resolution processing). Anchors 16 and coupon component tethers 18 are formed with coupons 20 being disposed entirely over sacrificial portions 14. FIG. 10 illustrates etching (e.g., wet or dry etching) sacrificial portions 14 so that coupons 20 are suspended by coupon component tethers 18 over substrate 10 defining gap 15. FIG. 11 illustrates stamp 40 picking up processed coupons 20 to micro-transfer print them to a destination substrate. Printing such processed coupons 20 would break (e.g., fracture) or separate coupon component tethers 18.

In some embodiments, an heterogeneous structure that includes coupon(s) 20 electrically connected to substrate circuit 12 by electrical connections 50 (e.g., according to FIG. 8) is or is processed to be a source wafer for heterogeneous structure(s), for example that can be printed (e.g., micro-transfer printed), for example in a method analogous to one shown in FIGS. 9-11.

Various embodiments of structures and methods were described herein that included (e.g., were made by) printing coupons. Printing may include or be micro-transfer printing. As used herein, micro-transfer-printing involves using a transfer device (e.g., an elastomeric stamp, such as a polydimethylsiloxane (PDMS) stamp) to transfer a coupon using controlled adhesion. For example, an exemplary transfer device can use kinetic or shear-assisted control of adhesion between a transfer device and a coupon. It is contemplated that, in certain embodiments, where a method is described as including micro-transfer-printing a coupon, other analogous embodiments exist using a different transfer method. In methods according to certain embodiments, a vacuum tool, electrostatic tool or other transfer device is used to print a coupon.

Examples of micro-transfer printing processes suitable for printing coupons onto substrates are described in U.S. Pat. No. 8,722,458 entitled Optical Systems Fabricated by Printing-Based Assembly, U.S. Pat. No. 9,362,113 entitled Engineered Substrates for Semiconductor Epitaxy and Methods of Fabricating the Same, U.S. Pat. No. 9,358,775 entitled Apparatus and Methods for Micro-Transfer-Printing, U.S. patent application Ser. No. 14/822,868, filed on Aug. 10, 2015, entitled Compound Micro-Assembly Strategies and Devices, and U.S. Pat. No. 9,704,821 entitled Stamp with Structured Posts, each of which is hereby incorporated by reference herein in its entirety.

Certain embodiments of the present disclosure were described above. It is, however, expressly noted that the present disclosure is not limited to those embodiments, but rather the intention is that additions and modifications to what was expressly described in the present disclosure are also included within the scope of the disclosure. Moreover, it is to be understood that the features of the various embodiments described in the present disclosure were not mutually exclusive and can exist in various combinations and permutations, even if such combinations or permutations were not made express, without departing from the spirit and scope of the disclosure. Having described certain implementations of heterogeneous wafer structures, heterogeneous semiconductor structures, methods of their fabrication, and methods of their use, it will now become apparent to one of skill in the art that other implementations incorporating the concepts of the disclosure may be used. Therefore, the disclosure should not be limited to certain implementations, but rather should be limited only by the spirit and scope of the following claims.

### PARTS LIST

10 substrate/wafer
12 substrate circuit
14 sacrificial portion
15 gap
16 anchor
18 coupon component tether
20 coupon/epitaxial layer
22 integrated circuit
24 tether/broken or separated tether
30 protection layer
40 transfer device/stamp
42 post/stamp post
50 electrical connection/wire/trace/interconnect
52 dielectric/dielectric layer
99 heterogeneous structure/heterogeneous wafer/source wafer

1. A method of making a heterogeneous structure, the method comprising:
providing a first substrate comprising a first material;
providing a second substrate comprising a printable processable coupon, wherein the coupon comprises a second material different from the first material; and
printing the coupon to the first substrate.

2. The method of claim 1, wherein the first substrate is a semiconductor substrate comprising a substrate circuit and the method comprises electrically connecting the substrate circuit to an integrated circuit formed in or on the coupon.

3. The method of claim 1, wherein the coupon comprises epitaxial material.

4. The method of claim 3, wherein the epitaxial material is unprocessed during the printing.

5. The method of claim 1, comprising pattern-wise covering the first substrate with a protection layer and subsequently processing the coupon separately from the first substrate.

6. The method of claim 1, comprising pattern-wise covering the coupon with a protection layer and subsequently processing the first substrate separately from the coupon.

7. The method of claim 1, wherein the first substrate is process-capable at a first resolution and the second substrate is process capable at a second resolution different from the first resolution and the method comprises processing the coupon at the first resolution.

8. The method of claim 7, wherein the first resolution is higher than the second resolution.

9. The method of claim 1, wherein the first substrate is an elemental semiconductor substrate.

10. The method of claim 1, wherein the second substrate is a compound semiconductor substrate.

11. The method of claim 1, wherein the coupon is a first coupon and the integrated circuit is a first integrated circuit, and the method comprises:
providing a third substrate comprising a printable processable second coupon, wherein the second coupon comprises a third material different from the first material and different from the second material; and
printing the second coupon to the first substrate.

12. The method of claim 11, wherein the second coupon comprises epitaxial material.

13. The method of claim 12, wherein the epitaxial material is unprocessed during the printing.

14. The method of claim 11, wherein the first substrate is process-capable at a first resolution and the third substrate is process capable at a third resolution different from the first resolution and wherein the second coupon is processed at the first resolution.

15. The method of claim 14, wherein the second substrate is process capable at a second resolution different from the first resolution and different from the third resolution.

16. The method of claim 14, wherein the first resolution is higher than the third resolution.

17. The method of claim 11, comprising pattern-wise coating the first substrate with a process-protective coating and processing the first coupon and the second coupon separately from the first substrate.

18. The method of claim 11, comprising pattern-wise coating the first substrate and the first coupon with a process-protective coating and processing the second coupon separately from the first substrate and the first coupon.

19. (canceled)

20. The method of claim 11, wherein the first substrate is a semiconductor substrate comprising a substrate circuit and the method comprises electrically connecting the substrate circuit to the second integrated circuit.

21. The method of claim 11, comprising patterning the first substrate and the second coupon in a common step.

22. The method of claim 1, comprising patterning the first substrate and the coupon in a common step.

23. (canceled)

24. The method of claim 1, wherein the coupon comprises a broken or separated tether after the coupon is printed to the first substrate.

25-45. (canceled)

46. The method of claim 1, comprising processing the coupon on the first substrate to form an integrated circuit.

47. The method of claim 11, comprising processing the second coupon to form a second integrated circuit.
